(19) United States
(12) Patent Application Publication
(10) Pub. No.: US 2007/0223549 A1
(43) Pub. Date: Sep. 27, 2007

(54) High-Power Optoelectronic Device with Improved Beam Quality Incorporating A Lateral Mode Filtering Section

(75) Inventors: Daniil Livshits, Dortmund (DE); Alexey Kovsh, Dortmund (DE); Alexey Zhukov, St.Petersburg (RU)

Correspondence Address: BROWN & MICHAELS, PC;400 M & T BANK BUILDING, 118 NORTH TIOGA ST, ITHACA, NY, 14850, US

(73) Assignee: NL NANOSEMICONDUCTOR GMBH, Dortmund (DE)

(21) Appl. No.: 11/277,268

(22) Filed: Mar. 23, 2006

(51) Int. Cl. H01S 5/00

(52) U.S. Cl. 372/45.01; 372/46.01

(57) ABSTRACT

An optoelectronic device includes a planar active element, a vertical waveguide surrounding the active element in the vertical direction, and a lateral waveguide comprising at least one active section and at least one filter section following each other in the longitudinal direction. At least part of the active element within the active section generates optical gain in response to above-threshold pumping. The broad lateral waveguide in the active section can localize multiple lateral optical modes. In the filter section, no lateral confinement is provided for the lateral optical modes. The device further comprises means to ensure low absorption loss in the filter section and, therefore, ensure high efficiency. In one embodiment low absorption loss is achieved by pumping of at least part of the active element within the filter section. In another embodiment, the active element has small overlap with the vertical optical modes.

### BACKGROUND OF THE INVENTION

1. Field of the Invention

The invention pertains to the field of optoelectronic devices. More particularly, the invention pertains to semiconductor diode lasers and superluminescent light-emitting diodes operating in the single spatial mode regime.

2. Description of Related Art

Semiconductor edge-emitting lasers are known in the art. In particular, single spatial mode edge-emitting lasers are known, which are capable of operating at the fundamental optical mode in both vertical and lateral directions. One advantage of a single spatial mode laser is a single lobe far field pattern and, as a result, the possibility for efficient coupling of the outgoing laser light into a single mode optical fiber or a single mode waveguide. If the laser is a multimode device, each mode has a different far field pattern and a different efficient focus distance, thus making it impossible to focus the emitted laser light into a single spot. This emphasizes the need for single mode devices.

The number of lateral modes generated by the laser is determined by the stripe width and by the refractive index difference between the stripe and the surrounding atmosphere. A laser having a narrow stripe width (usually few microns) typically operates as a single lateral mode laser.

In contrast, a laser having a broader stripe typically generates several lateral optical modes. At the same time, the broad-stripe laser operates at a smaller current density to reach the same total power. This is of high importance to reduce optical nonlinearities related to current injection, to suppress beam filamentation and pulse broadening. Moreover, the broad-stripe laser typically provides higher maximum output power due to better heat dissipation and reduced optical power density at the laser output facet.

The combined advantages of narrow-stripe lasers (stable single lateral mode operation) and broad-stripe lasers (better power characteristics) are often needed for particular applications. Specifically, there is a need for operation of a broad-stripe laser as a single lateral mode laser. For example, a broad-stripe laser provides a smaller lateral beam divergence (on the condition that the laser remains a single lateral mode laser). This is particularly important for high brightness laser bars.

Several methods have been disclosed to improve power and brightness characteristics of semiconductor edge-emitting lasers.

U.S. Pat. No. 6,782,024 discloses a high-power semiconductor laser diode having one or two “unpumped end sections”. One way of providing such an unpumped end section at one of the laser facets is to insert an isolation layer of a predetermined position, size, and shape between the laser diode's semiconductor material and the usually existing metallization. This method is capable of avoiding the degradation at the front facet of the laser caused by unwanted carrier recombination in this region. This method, however, is incapable of avoiding the excitation of higher-order modes.

U.S. Pat. No. 6,014,396 discloses a high-power semiconductor laser with essentially two resonator portions. The larger portion of the length of the resonator represents a single mode-confining region for propagation of light. The smaller portion of the length of the resonator represents a tapered region for permitting propagation of light with a diverging phase front to an output facet. The tapered region provides a sufficiently large aperture and therefore can improve the laser power level, while the single mode confining region provides spatial filtering to maintain a diffraction-limited beam at the output. A modification of this flared design of a high-power laser diode is disclosed in U.S. Pat. No. 6,798,815. This design consists of a segmented ridge waveguide having at least two straight segments, i.e. segments with constant, but different cross sections or widths, and at least one flared segment connecting the two different straight segments. Also disclosed is a segmented ridge waveguide design with three straight segments, at least two of them differing in cross section or width, and two flared segments connecting the differing straight segments.

A disadvantage of these methods, however, is that the flared shape of the laser resonator (as opposed to a simple rectangular shape) requires a certain precision of the lithography, etching, and other steps in fabrication. Also, the essential part of the laser is a narrow section which ensures single-mode operation of the laser. Its narrow width, however, which is typically a few microns, may cause additional difficulties in fabrication. Moreover, narrow width of this region may result in worse heat dissipation as compared to broader sections, which may result in diode overheating and related unwanted effects.

U.S. Pat. No. 6,804,280 discloses a semiconductor laser having a low beam divergence in the vertical direction by exploiting a photonic band gap crystal. However, the beam characteristics in the lateral direction need to be optimized by other methods.

Still another design of a high-power diode laser is disclosed in U.S. Pat. No. 6,862,300. The laser design in this patent relies on a structure including complex index guiding (CIG) elements on top of the laser diode. These CIG elements must contain at least one layer which provides the optical absorption of undesired modes and preferably contains an insulating layer as a first contact layer to the semiconductor. The principal design idea of this invention is a controllable introduction of additional optical loss for first and higher order modes. High-order lateral modes exhibit a broader extension in the lateral direction than the fundamental mode. Therefore, these undesired modes can be suppressed by introducing optically absorbing regions parallel to the ridge waveguide. A disadvantage of the method is additional complexity in the fabrication process due to a number of additional technological operations such as insulator deposition, photoresist deposition, photoresist etching, insulator etching, lift-off, absorbing layer deposition, and other technological steps.

U.S. Patent Publication 2004/0120377 discloses a broad area semiconductor laser with a singe-lobed far field pattern. FIG. 3(a) illustrates schematically a top view (viewed in the xy-plane) of a segmented gain section laser (300), designed in accordance with U.S. Patent Publication 2004/0120377, including a plurality of active sections (310) being spaced by passive sections (320). Each optically active section (310) includes a quantum well active region which can be pumped by current injection. The quantum well active region in each optically passive region (320) is subjected to quantum well intermixing (QWI). The optically passive regions act as a spatial mode filter for higher order modes. The semiconductor laser device may, therefore, be adapted to provide a substantially single mode output.

The operation principles of the laser of FIG. 3(a) are also discussed in “High power 1.55 μm laser diode sources with high transverse beam quality”, 1^{st} EMRS DTC Technical Conference (Conference of the Electro Magnetic Remote Sensing Defence Technology Centre), May 20-21, 2004, Edinburgh, Scotland, UK, O. P. Kowalski et al., herein incorporated by reference. In active sections, the propagating optical modes are laterally confined within the waveguide. In optically passive sections, the propagating optical modes are free to diffract horizontally. The degree of diffraction that occurs within the optically passive sections is determined by the order of the lateral optical mode. Higher order modes exhibit a greater degree of diffraction than the fundamental mode.

FIG. 3(b) shows an enlarged view of the laser of FIG. 3(a) with two adjacent optically active sections (310) separated by one optically passive section (320). FIG. 3(b) also illustrates schematically that the higher-order lateral optical mode (340) has large lateral angles of propagation and leaks away in the passive (filter) section (320). The fundamental lateral optical mode (330) has small lateral angles of propagation and therefore propagates through the filter section (320) with low loss, is coupled to the adjacent active section, and propagates further in the adjacent active section.

Thus, for a round-trip pass, the higher order modes undergo a greater degree of diffraction and therefore experience higher losses than the fundamental mode. Thus, the amplification per path for the fundamental lateral optical mode is higher than that for the higher-order lateral optical modes leading to an effective suppression of their oscillation.

U.S. Pat. No. 6,760,355 discloses a similar semiconductor laser device, which has been quantum-well intermixed and includes at least one section. The intermixed passive diffracting waveguide regions act as spatial mode filters which promote laser operation on a single spatial mode. Light in the higher-order modes experiences greater diffraction loss than the light of the fundamental mode as it propagates across the waveguide region. Gain profiling is alteration of a profile of a concentration of carriers within an active portion or region of the device. The device of U.S. Pat. No. 6,760,355 also includes means for providing gain profiling within an active section of the device.

U.S. Pat. No. 6,717,970 discloses another semiconductor laser device suitable for high-power single-spatial-mode operation. This device uses quantum well intermixing.

U.S. Pat. No. 6,717,971 discloses still another semiconductor laser device suitable for high-power single-spatial-mode operation. This device also uses quantum well intermixing.

The devices of U.S. Patent Publication 2004/0120377 and U.S. Pat. Nos. 6,760,355, 6,717,970, and 6,717,971 completely rely upon quantum well intermixing. In accordance with those methods, the quantum well in the passive sections of the device is subjected to quantum well intermixing. Due to quantum well intermixing, the quantum well in the passive sections has a larger band-gap than the as-grown quantum well in the active sections. Therefore the quantum well intermixed regions will provide a lower absorption of the lasing wavelength than the as-grown quantum well. Thus, the combination of two techniques, the high-order mode filtering and the quantum well intermixing, may produce a high power device operating at the fundamental lateral mode with low loss for the fundamental mode cause by integrated filter sections.

However, quantum well intermixing is not always acceptable for optoelectronic devices. Generally, the active region of a laser can be a bulk semiconductor layer (double heterostructure), single or multiple quantum wells, single or multiple layers of quantum wires, single or multiple layers of quantum dots or any combination thereof. Quantum well intermixing in its present form is limited to those devices which have a quantum well active region.

Semiconductor lasers based on bulk semiconductor layers are also known. A semiconductor layer is considered a “bulk” layer if its optical transition energy is not modified by the quantum-size effect nearly, i.e. the optical transition energy is nearly the same as the bandgap energy of the semiconductor material. For most semiconductor materials, the layer is preferably considered a bulk layer if its thickness is greater than approximately 20 nm. Quantum well intermixing is not applicable to lasers with a bulk active region because the bandgap of the bulk semiconductor material is practically insensitive to disordering of the potential profile as it is introduced by quantum well intermixing.

Lasers based on quantum wires or quantum dots also exist. Lasers based on quantum wires are not yet well developed. Lasers with an active region of self-organized quantum dots have demonstrated certain advantages over quantum well lasers for various device applications, in particular for application in optical communication systems at 1.3 μm. There is no reliable data as to whether or not a plane of self-organized quantum dots or a plane of quantum wires can be intermixed by a method similar to quantum well intermixing.

Also, a device fabricated by certain methods of quantum well intermixing can suffer from low external efficiency because of high loss in the intermixed sections. Quantum well intermixing typically requires thermal annealing, which may have an undesired effect on the active region of the laser. In particular, self-organized quantum dot lasers are known to be very sensitive to high-temperature treatment, and such a treatment can result in a significant unintentional shift of the lasing wavelength to a shorter wavelength (so-called, blue shift) in un-intermixed (active) sections of the laser.

Thus, there is a need for semiconductor lasers with high beam quality, particularly in single spatial mode lasers. More specifically, there is a need in the art for a high power single lateral mode optoelectronic device, which has the advantages of both single lateral mode lasers and wide stripe lasers. There is also a need for a simple fabrication method for a laser which combines the advantages of both single lateral mode lasers and wide stripe lasers. There is also a need for a fabrication method which is free of the disadvantages and limitations of quantum well intermixing and can be applicable to various types of the laser active regions.

### SUMMARY OF THE INVENTION

An optoelectronic device includes a planar active element, a vertical waveguide surrounding the active element in the vertical direction, and a lateral waveguide including at least one active section and at least one filter section following each other in the longitudinal direction. At least part of the active element within the active section generates optical gain in response to above-threshold pumping. The broad lateral waveguide in the active section can localize multiple lateral optical modes. In the filter section, no lateral confinement is provided for the lateral optical modes. The device further comprises means to ensure low absorption loss in the filter section and, therefore, ensure high efficiency. In one embodiment low absorption loss is achieved by pumping at least part of the active element within the filter section. In another embodiment the active element has small overlap with the vertical optical modes. The device operates as a single lateral mode optoelectronic device, possessing advantages of broad stripe optoelectronic devices.

The semiconductor optoelectronic device of the present invention includes a planar active element, the element being capable generating optical gain under appropriate pumping. The device is preferably based on one or more of various types of gain elements including, but not limited to, a bulk semiconductor layer, a quantum well, an array of quantum wires, an array of quantum dots, or any combination thereof. In one embodiment, the planar active element is a specially designed array of self-organized quantum dots. The optoelectronic device is free of the limitations and disadvantages of quantum well intermixing.

The device preferably further includes a vertical waveguide surrounding the active element in the vertical direction (the direction perpendicular to the active planar element). Light is confined in the vertical direction along the entire length of the device in the longitudinal direction. The vertical waveguide preferably confines only one (fundamental) vertical optical mode.

The device preferably further includes a lateral waveguide comprising at least one active section and at least one filter section. The active section and the filter section follow each other in the longitudinal direction.

The device preferably further includes a first pump element that pumps the planar active element within the active section such that at least a portion of the planar active element within the active section generates optical gain.

The lateral waveguide in the active section is preferably sufficiently broad such that multiple lateral optical modes can be localized. In the filter section, the lateral waveguide is modified such that no lateral confinement is provided for the lateral optical modes.

Therefore, leakage loss occurs for optical modes traveling along the filter section. Owing to the difference in effective lateral angles of propagation, higher leakage loss occurs for higher order optical modes. The lowest leakage loss occurs for the fundamental mode. The active section and the filter section are selected such that an amplification per path of the preselected lateral optical mode(s) is higher than an amplification per path for the lateral optical modes other than the preselected optical mode(s).

As a result, the device generates the reduced number of the lateral optical modes as compared to the number of the lateral optical modes, which can be localized in the active section of the lateral waveguide. Preferably, the device operates on the fundamental lateral mode as a single lateral mode optoelectronic device, possessing at the same time advantages of broad stripe optoelectronic devices.

The device further comprises means to ensure low absorption loss for propagating modes, the loss being caused by absorption of light by the active element in the filter section. This is achieved without any modification of the band gap of the active element by using quantum well intermixing. Owing to low absorption loss, high efficiency can be achieved.

In one embodiment, low absorption loss is achieved by pumping at least part of the active element within the filter section such that the active element within the filter section becomes nearly transparent for the propagating modes (the absorption loss caused by absorption of light by the planar active element within the filter section is low). To that end, in one embodiment, the device further comprises a second top contact mounted atop the filter section, electrically isolated from the first top contact. In another embodiment, the first and the second top contacts are electrically connected, but the total width of the second top contact is preferably narrower than the width of the first top contact.

In another embodiment, the active element is designed to have small overlap with the vertical optical modes (a low optical confinement factor in the vertical direction). In one embodiment, the active element is an array of self-organized quantum dots with low surface density. In another embodiment, the vertical waveguide is an asymmetric narrow waveguide.

Possible optoelectronic devices include, but are not limited to, a semiconductor laser, in particular, an edge-emitting laser or a mode-locked laser; an optical amplifier, in particular, an edge-emitting optical amplifier; and a superluminescent light-emitting diode.

In still another embodiment, the optoelectronic device is designed such that the significant leakage loss occurs for all optical modes at least one facet. In particular, this may be achieved by a combination of a two section device (an active section and a filter section) with one tilted facet adjacent to the filter section. As a result, an anti-reflectance (AR) facet with very low reflectance may be achieved by a simple fabrication method which is important, for example, for single-pass optical amplifiers or superluminescent light-emitting diodes.

### BRIEF DESCRIPTION OF THE DRAWINGS

FIG. 1 shows a layered structure of a semiconductor optoelectronic device in accordance with an embodiment of the present invention.

FIG. 2 shows a semiconductor optoelectronic device having two active sections and one filter section in accordance with an embodiment of the present invention.

FIG. 3(a) shows a prior art edge-emitting laser with a plurality of active sections being spaced by passive sections.

FIG. 3(b) shows an enlarged view of the laser of FIG. 3(a).

FIG. 4(a) shows a longitudinal cross-section of the device of FIG. 2 illustrating the spatial profiles of the fundamental vertical optical mode in different sections of the device.

FIG. 4(b) shows schematically a plane view of the device of FIG. 2 illustrating the spatial profiles of several lateral optical modes.

FIG. 5 shows a three-section device in an embodiment of the present invention.

FIG. 6 shows a longitudinal cross-section view of a device with the first and the second electrical contacts electrically isolated from each other.

FIG. 7(a) shows a plan-view of a device with the first and the second electrical contacts electrically connected to each other.

FIG. 7(b) shows a lateral cross-section of the filter section of the device of FIG. 7(a).

FIG. 8 illustrates another configuration of the second electrical contact in the device of FIG. 7, shown in a lateral cross-section view.

FIG. 9(a) shows a cross-section view of the filter section according to an embodiment of the present invention.

FIG. 9(b) shows a cross-section view of the filter section according to another embodiment of the present invention.

FIG. 10 shows a two-section device in an embodiment of the present invention.

FIG. 11 shows an edge-emitting mode-locked laser in an embodiment of the present invention.

FIG. 12 shows a plan view of a two-section device with one tilted facet according to an embodiment of the present invention.

FIG. 13 shows the lateral far-field pattern of a three-section quantum dot edge-emitting laser.

FIG. 14(a) shows the lateral far-field pattern of a three-section quantum dot edge-emitting laser in an embodiment of the present invention.

FIG. 14(b) shows the lateral far-field pattern of a single-section prior art quantum dot edge-emitting laser.

FIG. 15(a) shows the increase in pulse width generated by a prior art mode-locked laser upon average power.

FIG. 15(b) shows the improved performance of a mode-locked laser including a filter section with approximately 4 times shorter pulses compared to a prior art mode-locked laser for the same power level.

### DETAILED DESCRIPTION OF THE INVENTION

Filtering of Higher-Order Modes

A semiconductor optoelectronic device of the present invention exploits the filtering of higher order lateral modes. However, the device of the present invention does not use the quantum well intermixing required in U.S. Pat. No. 6,760,335, U.S. Patent Publication 2004/0120377 and the other prior art mentioned herein. The optoelectronic device may incorporate one or more of various types of gain elements. The optoelectronic device is free of the limitations and disadvantages of quantum well intermixing, which were discussed herein.

The following terms, as used throughout the present application, are defined as follows. The plane of the planar gain element is the (xy) plane, and the perpendicular direction is the z direction. Light propagates in the longitudinal direction (x). The direction (z) perpendicular to the planar gain element is termed the vertical direction. The lateral direction (y) is the direction perpendicular to both the longitudinal and the vertical directions.

The semiconductor optoelectronic device includes a planar active element, a vertical waveguide surrounding the planar active element in a vertical direction, a lateral waveguide including at least one active section and at least one filter section, and a first pump element that pumps the planar active element within the active section.

The device also includes means to ensure low absorption loss for propagating modes, the loss being caused by absorption of light by the active element in the filter section. With low absorption loss, high efficiency can be achieved. This is preferably achieved without the use of quantum well intermixing or any other technique that modifies the band gap of the active element.

The planar active element is capable of generating optical gain under appropriate pumping. The planar active element is chosen from materials including, but not limited to, a bulk semiconductor layer; a quantum well, an array of quantum wires, an array of quantum dots, or any combination thereof. In a preferred embodiment, the planar active element is an array of self-organized quantum dots as will be further described below. The optoelectronic device is free of the limitations and disadvantages of quantum well intermixing.

Light is confined in at least one vertical optical mode in a vertical direction along the entire length of the device in the longitudinal direction. In one preferred embodiment, the vertical optical mode is a single fundamental vertical optical mode.

In one embodiment, the vertical waveguide includes an optical cavity, a bottom reflector contiguous with the optical cavity, and a top reflector contiguous with the optical cavity on the side opposite the bottom reflector. The bottom reflector and the top reflector preferably each are an evanescent reflector or a multilayered interference reflector.

The lateral waveguide is preferably a ridge waveguide, a buried waveguide, an oxide confined waveguide, or any combination thereof. The active section and the filter section follow each other in a longitudinal direction. Light is confined in at least two lateral optical modes within the active section. Light is not confined in the lateral direction within the filter section.

In one embodiment, confinement of light in at least two lateral optical modes within the active section is provided by a sufficiently broad lateral waveguide within the active section. In one preferred embodiment, the broad lateral waveguide is broader than at least two wavelengths of light in a vacuum. In another preferred embodiment, the broad lateral waveguide is broader than at least five wavelengths of light in a vacuum. In still another preferred embodiment, the broad lateral waveguide is broader than at least ten wavelengths of light in a vacuum.

In the filter section, the lateral waveguide is modified such that no lateral confinement is provided for the lateral optical modes. This can be achieved by methods well-known in the art, which depend on the structure of the waveguide. For example, the lateral waveguide can be extended in the lateral direction. Alternatively, the waveguide structure can be modified by etching and/or overgrowth.

In one embodiment, the filter section is made broader than the active section. In one preferred embodiment, the filter section is broader than the active section by at least a factor of two.

The active section and the filter section follow each other in a longitudinal direction. In one preferred embodiment, the device includes one active section and one filter section. In another preferred embodiment, the device includes two active sections and one filter section in between the two active sections.

The first pump element pumps the planar active element within the active section such that at least a portion of the planar active element within the active section generates optical gain. In one preferred embodiment, the first pump element is an electrical bias element that pumps the planar active element by applying a forward bias to a p-n junction located within the planar active element.

Leakage loss occurs for optical modes traveling along the filter section. Due to the difference in effective lateral angles of propagation, higher leakage loss occurs for higher order optical modes. The active section and the filter section are selected such that an amplification per path for the preselected lateral optical mode(s) is higher than an amplification per path for the lateral optical modes other than the preselected optical mode(s).

In one preferred embodiment, the amplification per path for the preselected lateral optical mode is larger than the amplification per path for the lateral optical modes other than the preselected lateral optical mode by at least a factor of 2. In another preferred embodiment, the amplification per path for the preselected lateral optical mode is larger than the amplification per path for the lateral optical modes other than the preselected lateral optical mode by at least a factor of 5. In still another preferred embodiment, the amplification per path for the preselected lateral optical modes is larger than the amplification per path for the lateral optical modes other than the preselected lateral optical mode by at least a factor of 10.

In one preferred embodiment, the preselected lateral optical mode is a single fundamental lateral optical mode, such that the device operates in the fundamental lateral mode.

In a first preferred embodiment, a way to ensure low absorption loss for propagating modes in the filter section includes a second pump element that pumps at least part of the planar active element within the filter section such that the absorption loss caused by absorption of light by the planar active element within the filter section is low. In one preferred embodiment the absorption loss in the filter section is lower than 5 cm⁻¹. In another preferred embodiment the absorption loss in the filter section is lower than 3 cm⁻¹. In still another preferred embodiment the absorption loss in the filter section is lower than 1 cm⁻¹.

Another way to ensure low absorption loss for propagating modes in the filter section includes a planar active element which is designed such that the optical confinement factor in the vertical direction is low. In one preferred embodiment, the optical confinement factor in the vertical direction is lower than 1.5%. In another preferred embodiment, the optical confinement factor in the vertical direction is lower than 1%. In still another preferred embodiment, the optical confinement factor in the vertical direction is lower than 0.5%.

Therefore, in preferred embodiments, the device operates as a single lateral mode optoelectronic device, possessing at the same time advantages of broad stripe optoelectronic devices. Due to low absorption loss in the filter section, high efficiency can be achieved. This is achieved by simple methods, without the use of quantum well intermixing or any other technique for modification of the band gap of the active element.

One advantage of a single lateral mode broad stripe optoelectronic device is that it obtains a significantly higher output power in a single lateral mode than a conventional device at the same power density as the conventional device. This is particularly important for high power lasers and laser bars. Another advantage is having, for a given required output power, single lateral mode operation and considerably lower power density compared to conventional devices. This is particularly important for mode-locked lasers, as it suppresses non-linear effects and produces short pulses. This is also important for reducing the power level which results in catastrophic optical damage of the laser's facet owing to reduced optical power density.

The basic principles of the present invention are applicable to optoelectronic devices of various types including, but not limited to, a semiconductor laser (for example, an edge-emitting laser or a mode-locked laser), an optical amplifier (for example, an edge-emitting optical amplifier), and a superluminescent light-emitting diode.

Materials

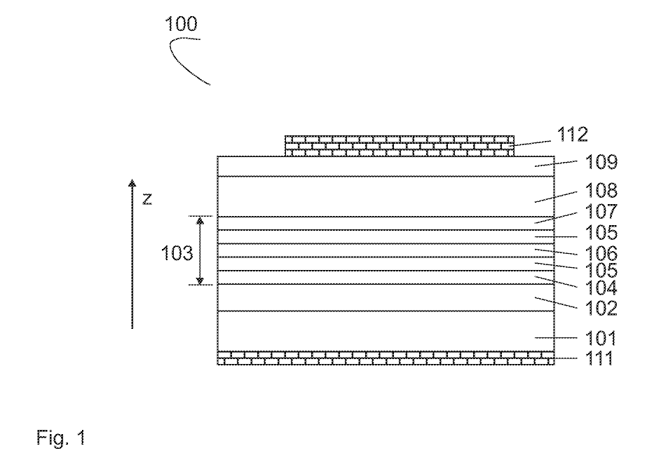

FIG. 1 shows a layered structure (100) of a semiconductor optoelectronic device in accordance with an embodiment of the present invention suitable for an edge-emitting semiconductor laser.

The layered structure (100) is grown epitaxially on an n-doped substrate (101). The growth direction is the vertical direction (z). The structure includes an n-doped cladding layer (102), a waveguide (103), a p-doped cladding layer (108), and a p-contact layer (109). The waveguide (103) includes a confinement layer (105) with a planar active element (106) inside the confinement layer. The waveguide (103) may also include an n-doped layer (104) and a p-doped layer (107).

The layered structure (100) may include an n-type metal contact (111) contiguous with the substrate (101). The layered structure (100) may also include a p-type metal contact (112) mounted atop the p-contact layer (109) at least in some parts of the p-contact layer (109). The waveguide (103) surrounded by two reflectors, an n-doped cladding layer (102) and a p-doped cladding layer (109), acts as a vertical waveguide that confines the optical modes in the vertical direction.

The substrate (101) is preferably formed from any III-V semiconductor material or III-V semiconductor alloy. Some examples for the substrate include GaAs, InP, or GaSb. GaAs or InP are preferably used depending on the desired emitted wavelength of laser radiation. Alternatively, sapphire, SiC or [111]-Si is used as a substrate for GaN-based structures (i.e. structures, the layers of which are formed of GaN, AlN, InN, or alloys of these materials). The substrate (101) is preferably doped by an n-type, or donor impurity. Possible donor impurities include, but are not limited to S, Se, Te, and amphoteric impurities like Si, Ge, and Sn, where the latter are introduced under such technological conditions that they are incorporated predominantly into the cation sublattice to serve as donor impurities.

The n-doped cladding layer (102) is preferably formed from a material lattice-matched or nearly lattice-matched to the substrate (101), is transparent to the generated light, and is doped by a donor impurity. In the case of a GaAs substrate (101), the n-doped cladding layer is preferably formed of a GaAlAs alloy.

The n-doped layer (104) of the waveguide (103) is preferably formed from a material lattice-matched or nearly lattice-matched to the substrate (101), is transparent to the generated light, and is doped by a donor impurity. For a GaAs substrate, the n-doped layer (104) of the waveguide is preferably formed of GaAs or of a GaAlAs alloy having an Al content lower than that in the n-doped cladding layer (102).

The p-doped layer (107) of the waveguide (103) is preferably formed from a material lattice-matched or nearly lattice-matched to the substrate (101), is transparent to the generated light, and is doped by an acceptor impurity. Preferably, the p-doped layer (107) of the waveguide is formed from the same material as the n-doped layer (104) but doped by an acceptor impurity. Possible acceptor impurities include, but are not limited to, Be, Mg, Zn, Cd, Pb, Mn and amphoteric impurities like Si, Ge, and Sn, where the latter are introduced under such technological conditions that they are incorporated predominantly into the anion sublattice and serve as acceptor impurities.

The p-doped cladding layer (108) is preferably formed from a material lattice-matched or nearly lattice-matched to the substrate (101), transparent to the generated light, and doped by an acceptor impurity. Preferably, the p-doped cladding layer (108) is formed from the same material as the n-doped cladding layer (102), but is doped by an acceptor impurity.

The p-contact layer (109) is preferably formed from a material lattice-matched or nearly lattice-matched to the substrate, is transparent to the generated light, and is doped by an acceptor impurity. The doping level is preferably higher than that in the p-cladding layer (108).

The metal contacts (111) and (112) are preferably formed from multi-layered metal structures. For example, the metal contact (111) is preferably formed from the structure Ni—Au—Ge and the metal contact (112) is preferably formed from the structure Ti—Pt—Au.

The confinement layer (105) is preferably formed from a material lattice-matched or nearly lattice-matched to the substrate (101), is transparent to the generated light, and is either undoped or weakly doped. The confinement layers are preferably formed from the same material as the substrate (101).

The active region (106) placed within the confinement layer (105) is preferably formed by any insertion, the energy band gap of which is narrower than that of the substrate (101). Possible active regions (106) include, but are not limited to, a single-layer or a multi-layer system of quantum wells, quantum wires, quantum dots, or any combination thereof. For a device on a GaAs-substrate, examples of the active region (106) include, but are not limited to, a system of insertions of InAs, In₁₋ₓGaₓAs, InₓGa_{1-x-y}Al_{y}As, InₓGa₁₋ₓAs_{1-y}N_{y} or similar materials.

Three-Section Device

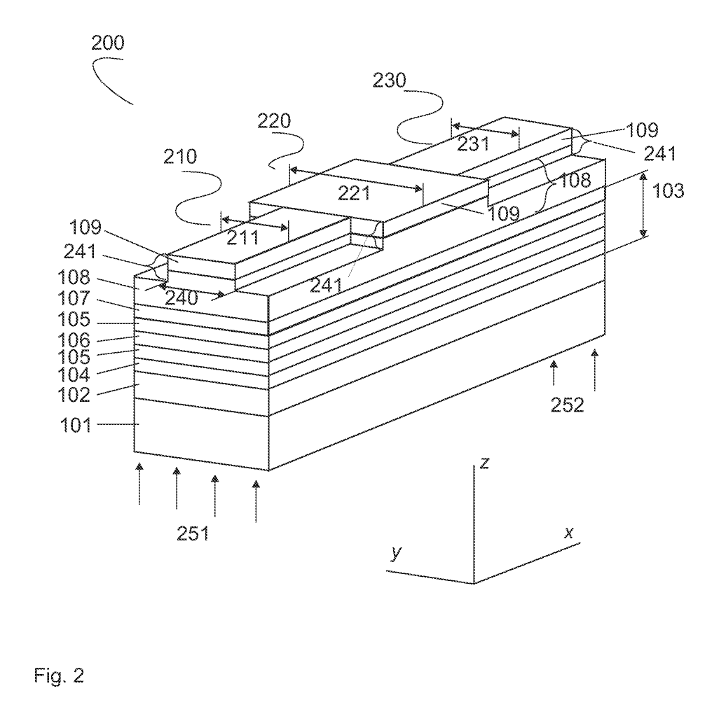

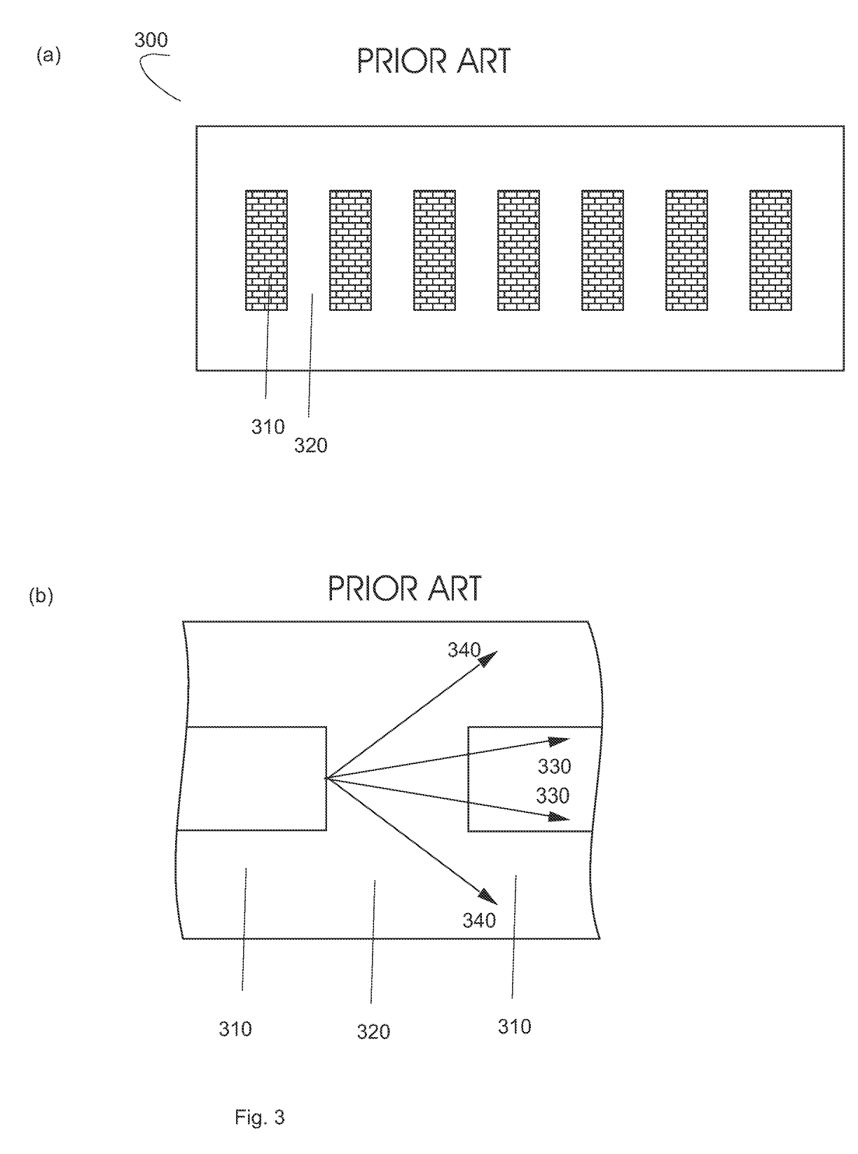

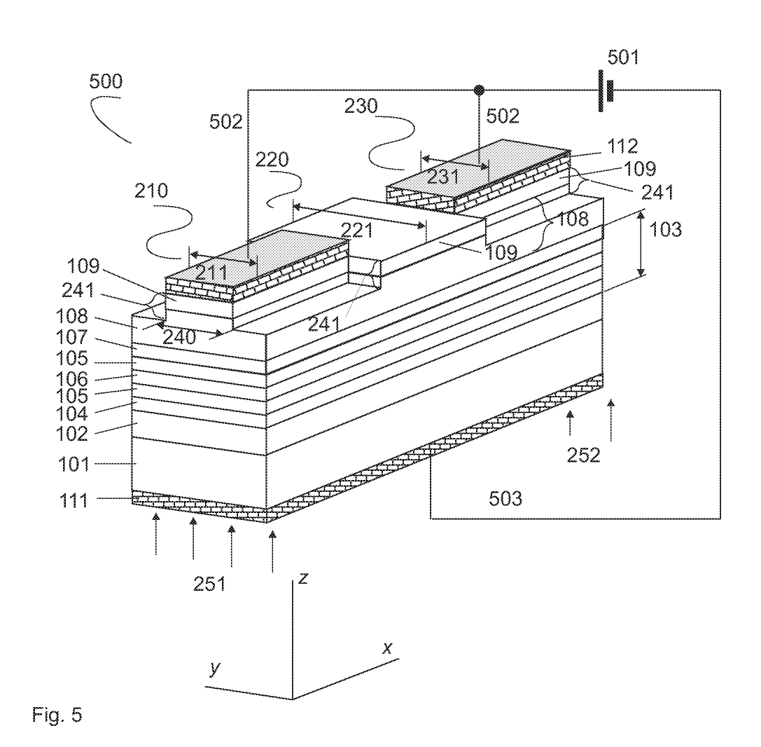

A semiconductor optoelectronic device (200) according to one embodiment is schematically shown in FIG. 2. The vertical optical waveguide (103) extends along an entire length of the device in the longitudinal direction (x). In the laser shown in FIG. 2(a), the lateral waveguide (240) is formed by a ridge structure (241). The ridge is fabricated through the p-contact layer (109) and the top part of the p-cladding layer (108). The device is terminated in the lateral direction (x) by a front facet (251) and a rear facet (252). The first pump element is not shown in FIG. 2 but will be described in connection with FIG. 5.

In FIG. 2, the lateral waveguide (the ridge) includes three sections: two active sections (210) and (230) and one filter section (220). Additional active sections and filter sections may be incorporated into the device, without deviating from the spirit of the invention. The ridge width (211) and (231) in the active sections (210) and (230) is sufficiently broad, for example broader than 5 micrometers, providing a lateral waveguiding effect for a plurality of lateral optical modes. The lateral waveguide profile in the active section (230) may be, but is not limited to, the same profile as the profile of the active section (210). In the filter section (220), the lateral waveguide (240) formed by the ridge (241) is modified such that the ridge width (221) is extended in the lateral direction (y). This significantly weakens and even suppresses the lateral waveguiding effect in the filter section (220). This results in a delocalization and leakage of the optical modes in the lateral direction when the light propagates through the filter section (220).

The device of FIG. 2 is suitable for use as an optically pumped optoelectronic device. For this use, an external source of optical pumping (not shown in FIG. 2) operates as a first pump source that pumps the planar active element within the active section.

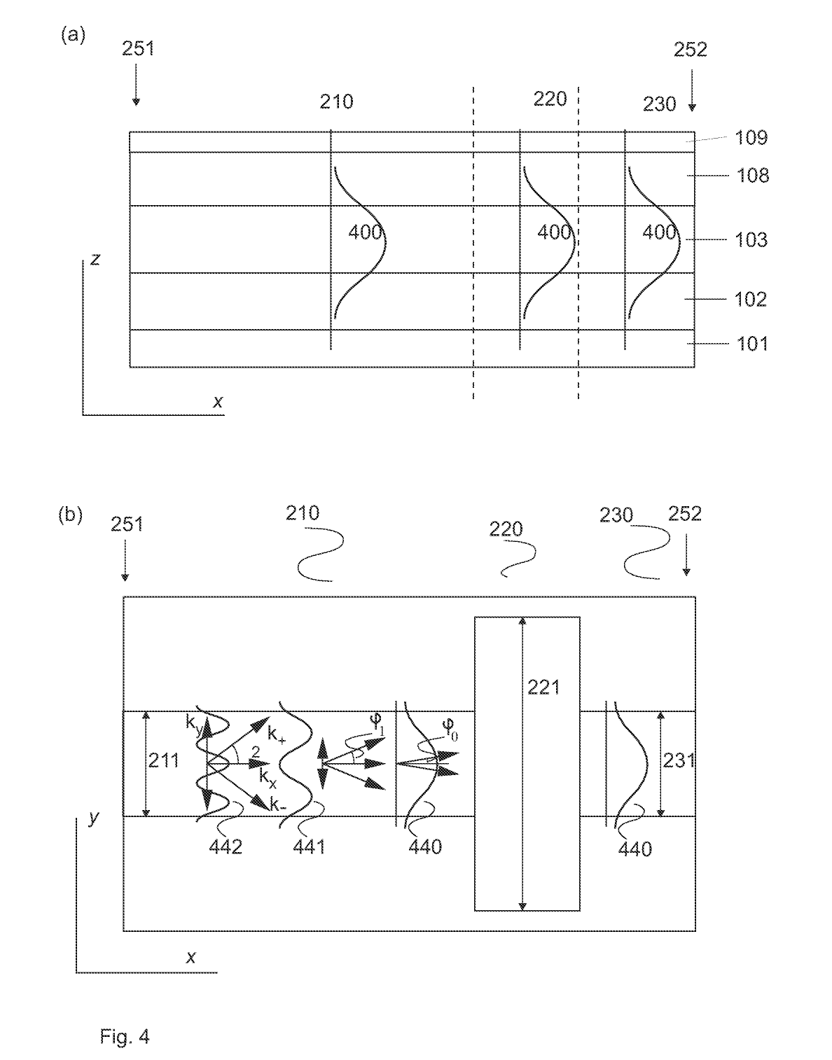

FIG. 4(a) shows a side cross-sectional view (in the (zx) plane) and FIG. 4(b) shows a plan view (in the (xy) plane) of the laser of FIG. 2. The three sections (210), (220), and (230) are easily viewed.

FIG. 4(a) also illustrates schematically the vertical spatial profile of the fundamental vertical mode (400). FIG. 4(a) illustrates that the fundamental vertical optical mode (400) is localized in the active and filter sections.

FIG. 4(b) also illustrates schematically the lateral spatial profiles of a few (three in this case) lateral optical modes, which are localized in the active section (210): the fundamental lateral optical mode (440), the first excited lateral optical mode (441), and the second excited lateral optical mode (442).

What is actually shown in FIG. 4 for each mode is a spatial distribution of the optical intensity (i.e., squared electric field) along the corresponding direction. The spatial distribution of the optical intensity along the lateral direction y for the fundamental lateral mode (440) has one maximum near the center of the ridge. The optical intensity decreases as the lateral coordinate along the y direction moves away from the center of the ridge. Thus, the shape of the lateral mode (440) is close to the Gaussian function. The spatial distribution of the optical intensity along the lateral direction y has two maxima for the lateral mode (441) and has three maxima for the lateral mode (442).

The spatial profile of the lateral optical mode in the active section may be written as follows:
E_{y}(x,y,z)=const×exp(ikₓx)×cos(k_{y}y+ψ)×E^{vertical}(z). (1)

It is convenient to write the electric field of the optical mode of Eq. (1) as a linear combination of two traveling waves in the (xy) plane:

$${E}_{y} ( x , y , z ) = const \times \frac{1}{2} \times \{ exp ( ⅈψ ) \times exp [ ⅈ ( {k}_{x} x + {k}_{y} y ) ] + exp ( - ⅈψ ) \times exp [ ⅈ ( {k}_{x } x - {k}_{y} y ) ] \} \times {E}^{vertical} ( z ) \qquad ( 2 )$$

It is convenient to define the effective lateral angle of propagation φ of the optical mode between the direction of the lateral wave vector \vec{k}=(kₓ, k_{y}) and the x axis:

$$φ = {tan}^{- 1} ( \frac{\vert {k}_{y} \vert}{{k}_{x}} ) . \qquad ( 3 )$$

FIG. 4(b) illustrates schematically that the effective lateral angle of propagation p increases with the order of the lateral optical mode,
φ₀<φ₁<φ₂< . . . . (4)

Higher-order lateral optical modes have larger lateral angles of propagation and leak away in the filter section (220) of the lateral waveguide. The fundamental lateral optical mode (440) propagates through the filter section (220), is coupled to the active section (230), and propagates further in the active section (230).

FIG. 5 illustrates an optoelectronic device (500) in accordance with another embodiment suitable for use as an electrically (current-injection) pumped optoelectronic device. Basically the device of FIG. 5 is similar to device of FIG. 2. In addition, FIG. 5 shows schematically the first pump element that pumps the planar active element (106) within the active sections (210) and (230) according to an embodiment of the present invention.

In this embodiment, the first pump element is an electrical bias element that pumps the planar active element by applying a forward bias to a p-n junction located within the planar active element (106). The p-n junction is preferably formed by the n-doped cladding layer (102), the n-doped layer (104), the p-doped cladding layer (108), and the p-doped layer (107).

The first pump element includes a source of DC voltage (501) connected by electrical connections (502) and (503) to the metal contacts (112) and (111), respectively. The metal contact (112) covers the active sections (210) and (230) of the device rather than covering the whole surface of the device. The metal contacts (112) and (111) and the electrical connections (502) and (503) jointly constitute first electrical contacts to the active sections. As shown in FIG. 5, the width of the first electrical contact is preferably nearly the same as the width (211) of the lateral waveguide in the active section in this embodiment.

The active region (106) within the active sections (210) and (230) generates optical gain when a forward bias is applied. Leakage loss occurs for optical modes traveling along the filter section, as was discussed with respect to FIG. 4(b). The amplification path is a closed path from the front facet (251) to the rear facet (252) and back to the front facet (251). The active sections and the filter section are selected such that the amplification per path for the preselected lateral optical modes is higher than the amplification per path for the lateral optical modes other than the preselected optical modes. In one preferred embodiment, the preselected lateral optical mode is the fundamental lateral optical mode, such that the device operates in the fundamental lateral mode.

In one preferred embodiment, the amplification per path for the preselected lateral optical mode is larger than the amplification per path for the lateral optical modes other than the preselected lateral optical mode by at least a factor of 2. In another preferred embodiment, the amplification per path for the preselected lateral optical mode is larger than the amplification per path for the lateral optical modes other than the preselected lateral optical mode by at least a factor of 5. In still another preferred embodiment, the amplification per path for the preselected lateral optical modes is larger than the amplification per path for the lateral optical modes other than the preselected lateral optical mode by at least a factor of 10.

In one embodiment of the present invention, the device operates as a high-power single lateral mode edge-emitting laser. Typically, a highly reflecting (HR) coating is put on the rear facet (252), and an antireflecting (AR) coating is put on the front facet (251). Then, the output laser light is emitted predominantly through the front facet (251).

In another embodiment, the device operates as a high-power single lateral mode optical amplifier. In yet another embodiment of the present invention, the device operates as a superluminescent light-emitting diode. In these embodiments, AR coatings are preferably put on both facets (251) and (252).

Means that Minimize Loss in the Filter Section

The first and the second preferred embodiments of the invention preferably include means that minimize loss in the filter section.

Because the first pump element does not pump the planar active element within the filter section, additional optical loss can arise when the optical mode is traveling through the filter section. This loss is caused by absorption of light by the unpumped active element within the filter section and therefore is called an absorption loss. In order to ensure acceptable efficiency in operation, the device of the present invention further includes ways to prevent or minimize this absorption loss.

The minimization of absorption loss may be achieved by a modification (namely by increasing) of the band gap of the active element. For example, the modification could be performed by using quantum well intermixing. Alternatively, the modification may be performed by selective regrowth by wider-bandgap material. However, these methods of fabrication are quite complicated, negatively affecting the yield and also suitable only for limited materials or limited types of the active element. For example, the regrowth method can not be applied to Al-containing materials, and the application of quantum-well intermixing to quantum dots is still questionable.

Therefore, the means that minimize absorption loss are preferably not based on any modification of the band gap of the active element. As a result, it is possible to avoid the difficulties and limitations which are inherent to the aforementioned methods of bandgap modification.

In a first preferred embodiment, the device includes a second pump element that pumps at least part of the planar active element within the filter section. This pumping leads to an increased concentration of charge carriers in the planar active element (106) within the filter section (220). As a result, the light absorption decreases. Pumping is selected such that the absorption loss is low. The absorption loss in the filter section is preferably lower than 5 cm⁻¹. The absorption loss in the filter section is more preferably lower than 3 cm⁻¹. The absorption loss in the filter section is still more preferably lower than 1 cm⁻¹.

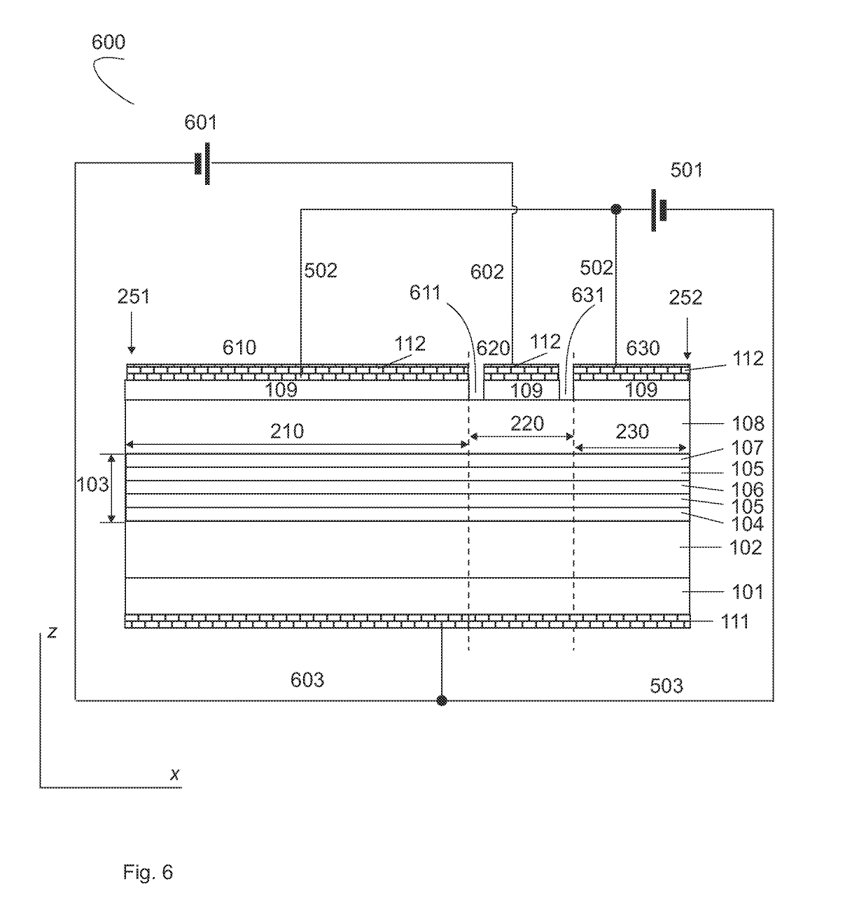

FIG. 6 shows the longitudinal cross-section (in the zx-plane) of the device (600) fabricated in accordance with an example of the first preferred embodiment. In the device (600) the second pump element is an electrical bias element that pumps a part of the planar active element within the filter section by applying a forward bias to a p-n junction located within the planar active element (106). The p-n junction is preferably formed by the n-doped cladding layer (102), the n-doped layer (104), the p-doped cladding layer (108), and the p-doped layer (107).

One part (620) of the metal contact (112) covers the filter section (220) of the device, while the other parts (610) and (630) of the metal contact (112) cover the active sections (210) and (230).

The first pump element functions similarly to the first pump element in the device of FIG. 5. The second pump element includes a source of DC voltage (601) connected by electrical connection (603) to the metal contact (111) and by electrical connection (602) to the parts (620) of the metal contact (112).

The metal contact (111), the parts (610) and (630) of the metal contact (112) that cover the active sections (210) and (230), and the electrical connections (502) and (503) jointly constitute first electrical contacts to the active sections. The metal contact (112), the part (620) of the metal contact (112) that covers the filter section (220), and the electrical connections (602) and (603) jointly constitute second electrical contacts to the active sections.

The first and the second contacts are electrically isolated from each other. This is achieved by separation of the parts (610) and (630) of the metal contact from the part (620) of the metal contact. In addition, the p-contact layer (109) can be partly removed (etched) by forming isolating trenches (611) and (631) for better isolation.

If the pumping provided by the second pump element is sufficiently strong, the active element within the filter sections can generate optical gain. Thus the absorption loss in the filter section completely disappears. However the filtering of the higher-order modes is suppressed because of gain-guided waveguiding effect in the lateral direction.

Therefore, in one preferred embodiment, the forward bias applied to the second contact is selected such that the current density, passing through the active element within the filter section, approximates the transparency current density of the material of the active element. At the transparency current density, the material becomes nearly transparent (i.e. the absorption is close to zero) for the photon energies nearly equal to the band gap energy of the active element.

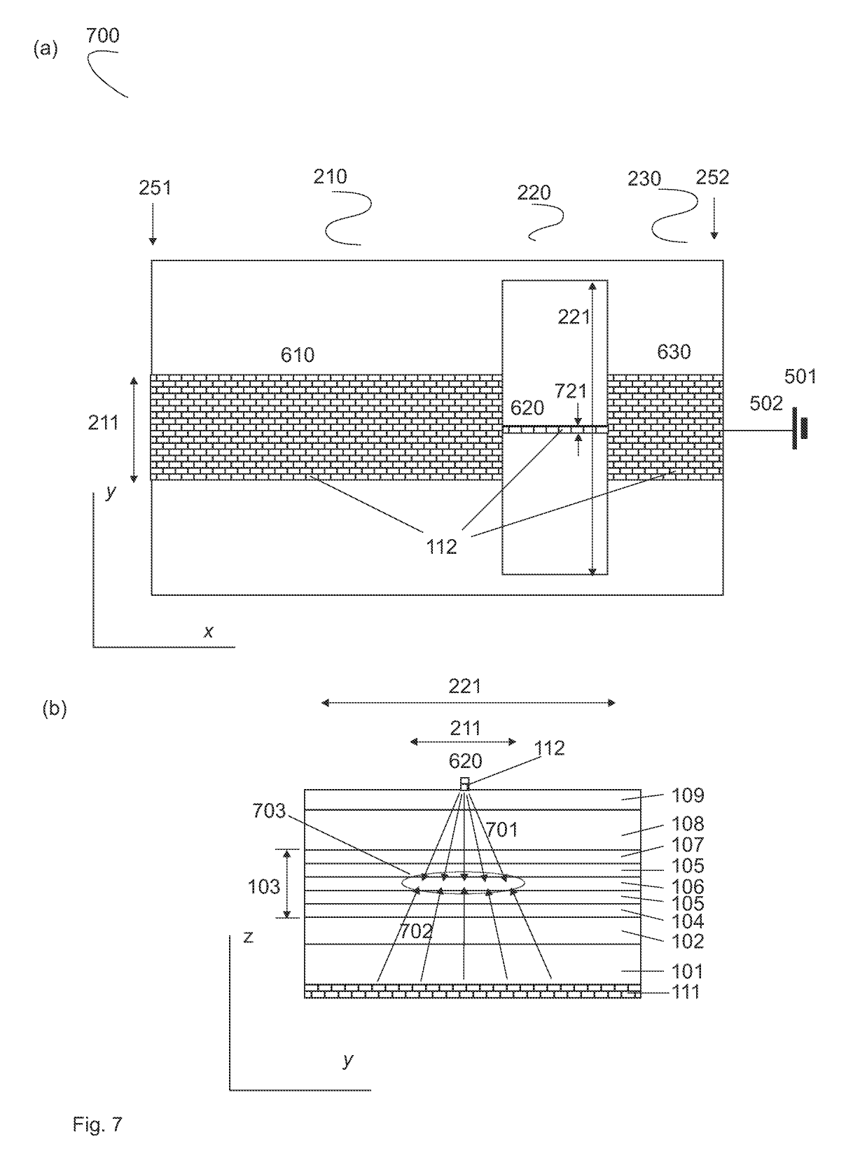

FIG. 7(a) illustrates a plan-view of a device (700) fabricated in accordance with an alternative example of the first preferred embodiment. One feature of this example is that the first and the second electrical contacts are electrically connected.

One part (620) of the metal contact (112) partly covers the filter section (220) of the device, while the other parts (610) and (630) of the metal contact (112) cover the active sections (210) and (230). The parts (610), (620), and (630) are in electrical contact.

The metal contact (111) (not shown in FIG. 7(a)), the parts (610) and (630) of the metal contact (112) that cover the active sections (210) and (230), and the electrical connections (502) and (503) (not shown in FIG. 7(a)) jointly constitute first electrical contacts to the active sections. The metal contact (111) (not shown in FIG. 7(a)) and the part (620) of the metal contact (112) that covers the filter section (220), jointly constitute second electrical contacts to the filter sections.

The first and the second electrical contacts are electrically connected in this example. Therefore, the first pump element can also function as the second pump element. The first pump element functions similarly to the first pump element in the device of FIG. 5 and FIG. 6. When the forward bias is applied from the DC voltage source (501) to the first contact in order to provide optical gain in the planar active element within the active sections (210) and (230), the bias is simultaneously applied to the second contact. This leads to an increase in the concentration of charge carriers in the planar active element (106) within the filter section (220). As a result, light absorption decreases.

If the second electrical contact (620) has the same width as the first electrical contacts (610) and (630), then the pumping of the active element (106) within the filter section (220) is sufficiently strong, and the active element within the filter sections generates optical gain. Thus the absorption loss in the filter section completely disappears. However the filtering of the higher-order modes is suppressed because of a gain-guided waveguiding effect in the lateral direction.

Therefore, the second electrical contacts (620) are preferably made narrower than the first electrical contacts (610) and (630) in order to decrease a total consumption of the electrical current by the device. The total width (721) of the second electrical contact (620) is preferably narrower than the width (211) of the first contacts (610) and (630) by at least a factor of two. The total width (721) of the second contact (620) is more preferably narrower than the width (211) of the first contact by at least a factor of five. The total width of the second contact is still more preferably narrower than the width of the first contact by at least a factor of ten.

FIG. 7(b) shows a lateral cross-section of the filter section of the device of FIG. 7(a). Arrows (701) and (702) schematically illustrate in FIG. 7(b) injection of holes and electrons, respectively, to the active planar element (106). There is a certain spread of the charge carriers in the active element. A characteristic distance (703) of this spread depends on coefficients of diffusion, thickness of the device, and other material properties and parameters of the device. Typically this distance is on the order of 1-10 micrometers.

The characteristic distance (703) of the charge carrier spread in the active element is shown in FIG. 7(b) to be nearly of the same width as the width (211) of the lateral waveguide in the active sections. Therefore, as the optical mode travels from one active section to another active section through the filter section, it travels through the region with reduced absorption or a nearly transparent region. However, if the width of the active section is chosen to be broader than the characteristic distance of the charge carrier spread in the active element, there can be regions in the filter sections with high absorption of optical modes traveling through the filter section.

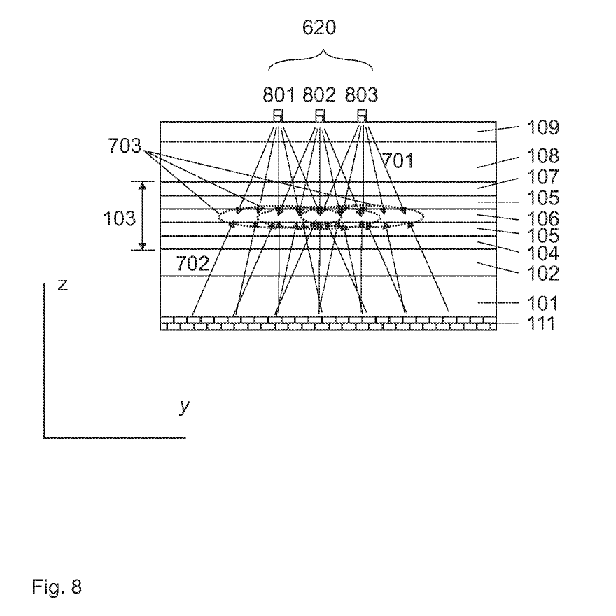

FIG. 8 illustrates another possible configuration of the second contact shown in a lateral cross-section view (in the (zy) plane). One feature of this example is that the second contact (620) represents a plurality of subcontacts (801), (802), and (803). These subcontacts are electrically connected with each other through the connection with the first electrical contacts (610) and (630) (not shown in FIG. 8). The distance between the adjacent subcontacts is smaller than the characteristic distance of the charge carrier spread in the active element. As a result regions (703) of the charge carrier spread overlap in the active element within the filter section.

Although three subcontacts are shown in FIG. 8, the number of subcontacts may vary. The number of contacts are preferably chosen such that the total area of the carrier spread completely covers the region where the optical mode travels.

In a second preferred embodiment, there is no second pump element that pumps the active element with the filters sections. This may be advantageous over the first preferred embodiment due to less consumption of the electric current and simpler device fabrication and operation.

On the other hand, no transparency occurs in the active element within the filter sections. At the same time, to ensure high efficiency of operation, the filter sections of the device should provide low absorption for the light modes that travels through the filter sections. This is achieved by using an active element designed to have small overlap with the vertical optical modes. Then it results in a low modal absorption in the filter section.

The optical confinement factor in the vertical direction is preferably lower than 1.5%. The optical confinement factor in the vertical direction is more preferably lower than 1.0%. The optical confinement factor in the vertical direction is still more preferably lower than 0.5%.

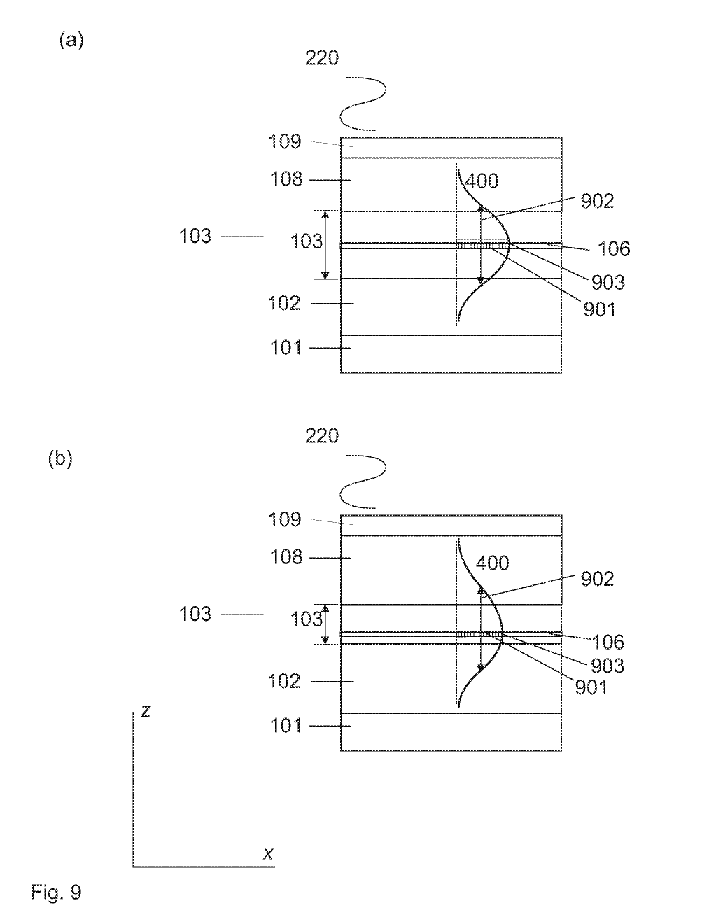

FIG. 9(a) shows a cross-section view of the filter section (220). The overlap of the vertical optical mode (400) with the active element (106) is known as an optical confinement factor in the vertical direction, F. The part of the optical mode (400), which contributes to the optical confinement factor, is illustrated in FIG. 9 by a hatched area (901).

The optical confinement factor F is calculated as:

$$Γ = \frac{{\int }_{( 106 )} {[ {E}^{vertical} ( z ) ]}^{2} ⅆ z}{{\int }_{- ∞}^{∞} {[ {E}^{vertical} ( z ) ]}^{2} ⅆ z} \qquad ( 5 )$$

In Eq. (5) the integral in the dividend is taken within the active element (106), while the integral in the divisor is taken over the whole layered structure in the vertical direction (z).

Full width (902) of the optical mode (400) at half maximum is usually considered as an effective width of the mode. If an active element (106) is several times narrower than the effective width (902) of the vertical optical mode, the optical confinement factor linearly depends on the width of the active element (106). Therefore, a low optical confinement factor can be achieved by thinning the active element.

The typical effective width of the fundamental vertical mode is a few hundred nanometers. A situation where the active element (106) is several times narrower than the effective width (902) of the vertical optical mode may take place if the active element is a quantum dot or quantum wire array (where the typical width in the vertical direction is a few nanometers), or a quantum well (where the typical width is few ten nanometers). A bulk semiconductor material as the active element in this situation is also possible. Therefore, a sufficiently narrow optical confinement factor in the vertical direction can be achieved by thinning the active element.

If the active element is an array of quantum dots, the quantum dots preferably cover only part of the (xy) plane. As a result, an overlap of the quantum dot active element with the optical mode is reduced compared to a quantum well with the same width in the vertical direction. The optical confinement factor in the vertical direction for a quantum dot active element may be effectively controlled by changing the surface density of the quantum dots. Using this property, the optical confinement factor may be significantly reduced because a diluted array of quantum dots will provide very small overlap of the active element with the optical mode.

In one embodiment, the active element is an array of self-organized quantum dots with a low surface density of quantum dots. If several planes of quantum dots jointly constitute the active element, the surface density of quantum dots in one plane should be multiplied by the number of planes. The surface density of quantum dots is preferably lower than 5×10¹¹ cm⁻². It is more preferable that the surface density of quantum dots is lower than 3×10¹¹ cm⁻². It is still more preferable that the surface density of quantum dots is lower than 1×10¹¹ cm⁻². The surface density of quantum dots can be readily optimized by changing the number of quantum dot planes that constitute the active element.

FIG. 9(b) shows a cross-section view of the filter section according to another embodiment. In this embodiment, sufficiently low optical confinement factor in the vertical direction is achieved by using an asymmetric narrow waveguide as the vertical waveguide. A feature of this embodiment is that the planar active element may include a bulk semiconductor layer, a quantum well, an array of quantum wires, an array of quantum dots, and any combination thereof.

A vertical waveguide is usually referred to as a broad optical waveguide if its width is close to the cutoff of the second-order transverse mode. In contrast, the width of the vertical waveguide (103) is preferably narrower than ½ of the cutoff of the second-order vertical optical mode. It is more preferable that the vertical waveguide is narrower than ⅓ of the cutoff of the second-order vertical optical mode. It is still more preferable that the vertical waveguide is narrower than ¼ of the cutoff of the second-order vertical optical mode.

A vertical waveguide is usually referred to as a symmetric optical waveguide if the fundamental vertical mode has the maximum in the center of the waveguide. This is usually achieved by symmetry of a compositional (and, therefore, a refractive index) profile with respect to the waveguide center. In contrast, in an embodiment of the present invention, the maximum (903) of the fundamental vertical mode (400) is shifted from the center of the vertical waveguide (106) as shown in FIG. 9(b). It is preferable that the maximum of the fundamental vertical mode is shifted from the center of the vertical waveguide by more than ⅙ of the vertical waveguide width. It is more preferable that the maximum of the fundamental vertical mode is shifted from center of the vertical waveguide by more than ¼ of the vertical waveguide width.

The desired asymmetry is preferably achieved by using cladding layers (102) and (108) of different refractive indexes. As shown in FIG. 9(b), the maximum (903) of the fundamental mode (400) is shifted towards the n-type cladding layer (102) because the refractive index in the n-type cladding layer (102) is higher than the refractive index in the p-type cladding layer (108).

Relatively narrow asymmetric vertical waveguides are advantageous over the symmetric broad vertical waveguides, which are conventionally used in semiconductor optoelectronic devices. This is because the relatively narrow waveguide allows the optical loss in the waveguide, which become important at high currents, to be minimized. At the same time, the waveguide asymmetry helps to minimize the loss in that cladding layer of two cladding layers, where the free-carrier absorption coefficient is higher. In a typical situation, the p-type doped material is characterized by a higher coefficient of free-carrier absorption. Therefore, a shift of the mode maximum to the n-type cladding layer, as shown in FIG. 9(b), is usually advantageous.

Two-Section Device

The efficient selection of the lateral optical modes of an optoelectronic device may alternatively be achieved by a two-section device. All features of the three-section devices, taken alone or in combination, as discussed above, are applicable to a two-section device. A two-section device may be advantageous over a three-section device because of simplified processing and wiring.

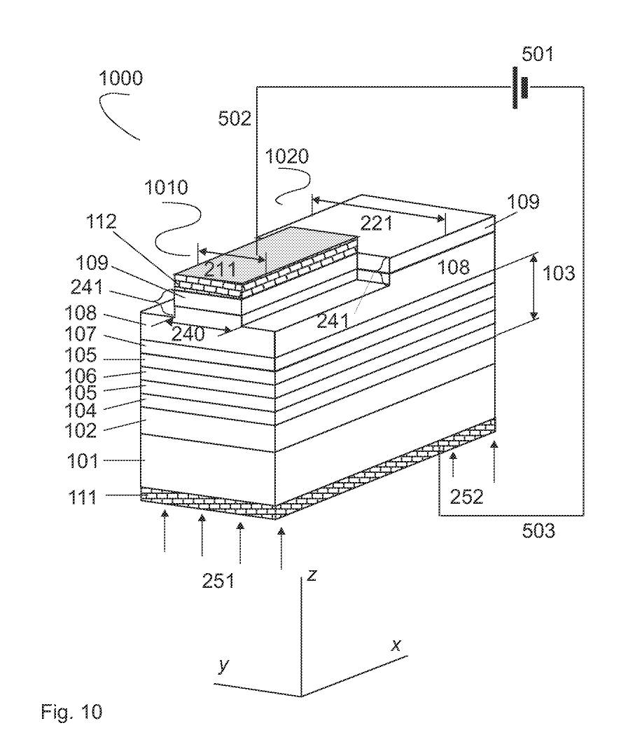

FIG. 10 shows schematically one embodiment of a two-section device (1000) suitable for use as an edge-emitting laser, an edge-emitting optical amplifier or a superluminescent light-emitting diode. The device (1000) is basically the same as the device (500) of FIG. 5 except that, instead of the two active sections (510) and (530) and the one filter section (520) in the device (500), the device (1000) includes one active section (1010) and one filter section (1020).

In the filter section (1020), the lateral waveguide (240) formed by the ridge (241) is modified such that the ridge width (221) is extended in the lateral direction (y). This significantly weakens and even suppresses the lateral waveguiding effect in the filter section (1020). This results in a delocalization and leakage of the optical modes in the lateral direction when the light propagates through the filter section (1020).

Single Lateral Mode Mode-Locked Laser

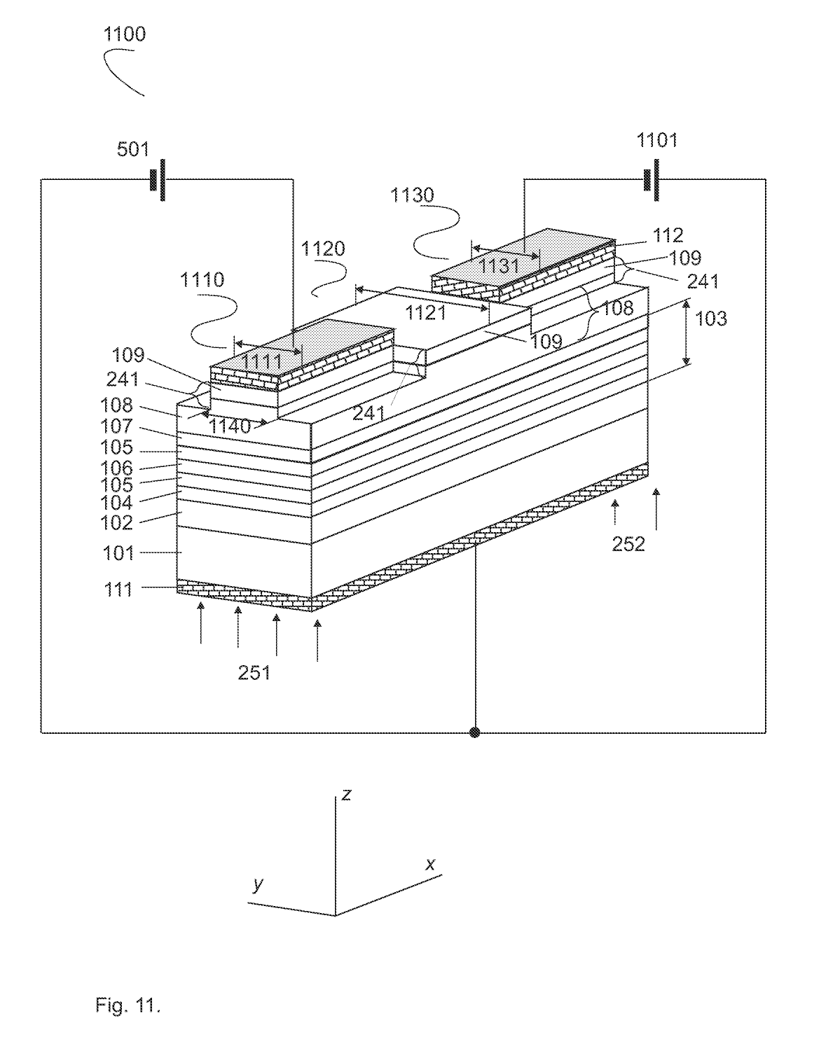

FIG. 11 illustrates a mode-locked laser (1100) according to an embodiment of the present invention. The device includes three sections: the first, active section (1110), the second, filter section (1120), and the third, absorber section (1130). The active section (1110) operates under a forward bias (501). The passive section operates under a reverse bias (1101) or under zero bias and acts as a saturable absorber of light. The reverse or zero bias (1101) is applied via the n-type metal contact (111) and the part of the p-type metal contact (112) that covers the absorber section (1130). The active section (1110) and the absorber section (1130) are electrically separated by the filter section (1120).

The filter section (1120) is selected such that it provides only a weak or no waveguiding effect for lateral optical modes. This results in a delocalization and leakage of the optical modes in the lateral direction. The lateral widths (1111) and (1131) of the lateral waveguide (1140) in the active section (1110) and the absorber section (1130), respectively, are preferably broader than 5 micrometers, providing a lateral waveguiding effect for a plurality of lateral optical modes. One example of a lateral waveguide profile for the third section is the same profile as the profile of the first section.

In the particular embodiment of FIG. 11, the lateral waveguide in the filter section (1120) is formed such that its width (1121) is extended in the lateral direction. This significantly weakens and even suppresses the lateral waveguiding effect. The leakage loss in the filter section is very different for different lateral optical modes. The particular profile is selected such that the positive feedback occurs only for one preselected lateral optical mode. Preferably, the preselected lateral optical mode is the fundamental lateral optical mode.

One important difference between a conventional mode-locked laser and a mode-locked laser of the present invention is the dimension of the filter section. In a conventional mode-locked laser, a current isolation trench, separating the active section and the absorber section has a standard width of 5 to 20 micrometers. In the present invention a current separating region has a size in the longitudinal direction (x) an order of magnitude larger than that in a conventional mode-locked laser. Its larger size allows this section of the device to work as a lateral mode filter and, simultaneously, improves the electrical isolation. A preferred length of the filter section is about 100 μm to 1 mm. It should be noted that a filter section with a length of 500 μm provides 100 times higher resistance than a 5 μm wide isolation trench.

Using a filter section in a mode-locked laser permits single-lateral mode lasing in a laser with a broad ridge. The advantages are emphasized below, in connection with the examples.

Anti-Reflectance Facet

In still another embodiment, an optoelectronic device is designed such that the significant leakage loss occurs for all optical modes at least at one facet. In particular, this may be achieved by a combination of the two section device including an active section and a filter section with one tilted facet adjacent to the filter section. Tilt of the facet decreases the efficiency of coupling of the light reflected back to the active section. The filter section, adjacent to the tilted facet, further decreases this coupling efficiency. As a result, an anti-reflectance (AR) facet with very low reflectance is achieved by a simple fabrication method. In one embodiment, the anti-reflectance facet has a reflectance lower than 1%. In another embodiment, the anti-reflectance facet has a reflectance lower than 0.1%.

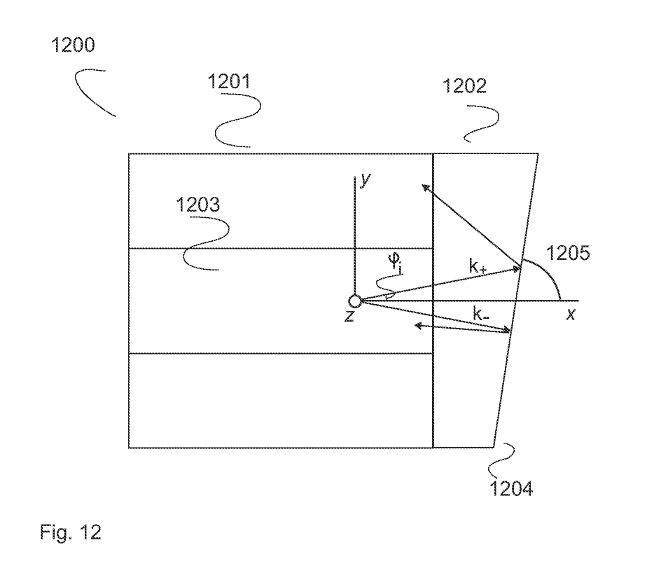

FIG. 12 illustrates schematically a plan view of a two-section device (1200), similar to what is shown in FIG. 10, including an active section (1201) and a filter section (1202). The active section (1201) includes a ridge waveguide (1203), where one or several lateral optical modes can propagate along the lateral waveguide. The filter section (1202) is selected such that it provides only a weak or no waveguiding effect for lateral optical modes. The filter section (1202) is adjacent to an output facet (1204) of the device (1200). The output facet (1204) is tilted with respect to the (yz) plane such that the angle (1205) between the facet (1204) and the longitudinal direction x does not equal the normal angle of π/2.

All lateral optical modes, including the fundamental optical modes, propagate through the filter section (1202) and reflect at the tilted facet (1204). Because of the non-normal incidence of light onto the tilted facet (1204), the coupling efficiency of the reflected light back to the ridge waveguide (1203) of the active section (1201) is significantly reduced. This is illustrated in FIG. 12 where a lateral optical mode is represented as a linear combination of two traveling waves in the lateral plane having lateral wave vectors k+ and k−, as was discussed above in conjunction with FIG. 4(b). The lateral optical mode is illustrated to have an effective lateral angle of propagation φᵢ. As illustrated in FIG. 12, at least one traveling wave (having the lateral wave vector k+) can not be coupled back to the ridge waveguide (1203) of the active section (1201). Therefore, a significant leakage loss occurs for this optical mode at the tilted facet (1204).

The length of the filter section (1202), the width of the ridge waveguide (1203) of the active section (1201), and the tilt angle (1205) of the facet (1204) are preferably preselected such that the significant leakage loss occurs for all optical modes which may be supported by the active section (1201). As a result, the facet (1204) is characterized by very low reflectance for the light propagating inside the device (1200). Therefore the facet (1204) may be considered as an anti-reflectance (AR) facet having very low reflectance.

AR-facets formed by the method of the present invention may be used, for example, for single-pass optical amplifiers or superluminescent diodes with an advantage of the simplicity of fabrication of such AR facets compared to conventional methods.

Examples of Three-Section Lasers

A three-section edge-emitting laser has been fabricated according to the embodiment illustrated in FIG. 5. The laser is a quantum-dot laser emitting at 1250 nm. The InAs/InGaAs quantum dot active region in a GaAs matrix has been fabricated similar to the method described in Kovsh et al. “InAs/InGaAs/GaAs quantum dot lasers of 1.3 μm range with high (88%) differential efficiency”. Electronics Letters, Vol. 38 (19), pp. 1104-1106 (2002), herein incorporated by reference.

Novel to the design is a three-section device according to the embodiment of FIG. 5. The width of the ridge (211) and (231) in the active sections (210) and (230) in the lateral direction is 18 micrometers. The length of the active section (210) is 1.7 mm. The length of the filter section (220) is 0.5 mm. The length of the active section (230) is 0.27 mm. The threshold current density of the laser is Jₜₕ˜100 A/cm².

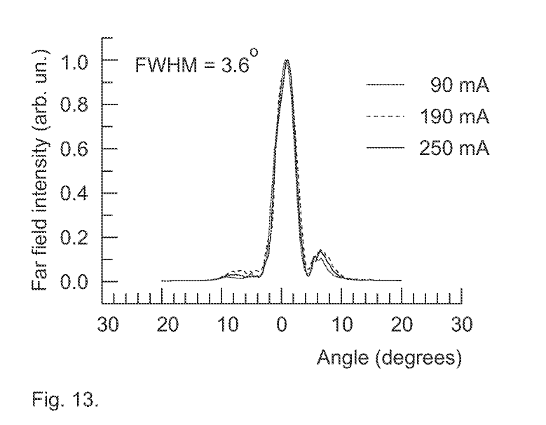

FIG. 13 shows the lateral far field pattern at three values, 90 mA (dotted line), 190 mA (dashed line) and 250 mA (solid line), of the drive current. The maximum drive current of 250 mA corresponds to a current density of about 550 A/cm², which is about 5.5 times the threshold current density. For such a broad ridge, the far field pattern shows a narrow central lobe having 3.6 degrees of full width at half maximum (FWHM). Comparison of the lateral far field pattern at three drive currents shows that the far field does not change with the drive current. 90% of the optical power is concentrated in a single lobe having 3.6 degrees of the lateral beam divergence. The narrow single-lobe lateral far field in a laser with a broad ridge (w=18 μm) is possible due to the efficient filtering of high-order lateral modes by the filter section of the laser.

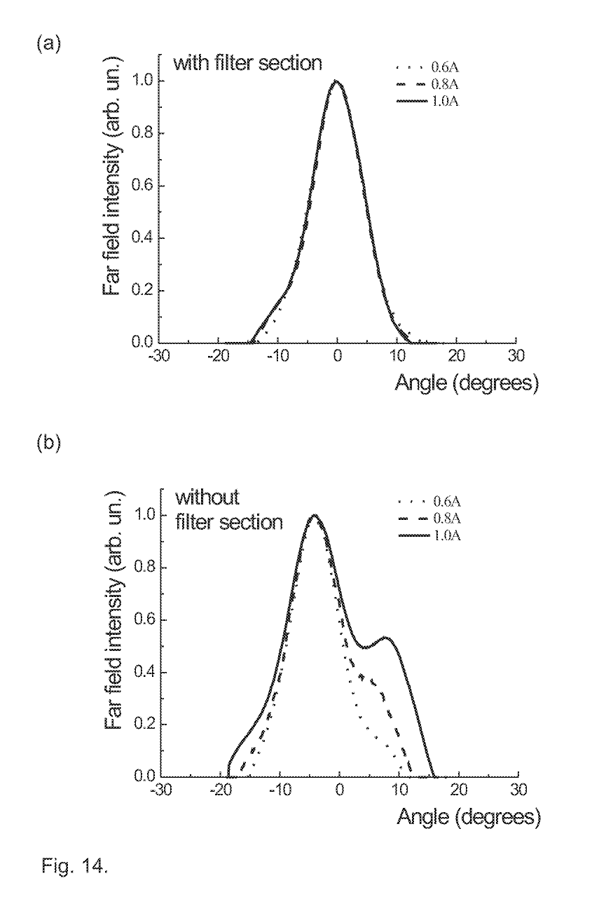

Another example is illustrated in FIG. 14. This figure demonstrates the lateral far field pattern at different values of the drive current. The device of FIG. 14(a) was fabricated as a three-section edge-emitting laser in accordance with the embodiment illustrated in FIG. 5. The laser is a quantum-dot laser emitting at 1260 nm. The width of the ridge (611) and (631) in the lateral direction is 20 μm (micrometers). The total device length is 4000 μm, 500 μm of which is the filter section inserted in the center. The device of FIG. 14(b), for comparison, was fabricated from the same epitaxial wafer and using the same technological process as of device of FIG. 14(a). The only difference is that the device of FIG. 14(b) represents a conventional (single-section) edge-emitting laser having a ridge width of 20 μm in the lateral direction.

As seen in the data presented in FIG. 14(a), the lateral far field pattern of the three-section device remains essentially Gaussian up to the maximum drive current of 1.0 A (which corresponds to the current density of about 1.5 kA/cm²). The far field pattern shows a FWHM of about 10-10.1 degree regardless of the drive current. Approximately 96% of the total optical power is concentrated in a central lobe of the far field pattern.

A very different situation takes place for the conventional device of FIG. 14(b). The lateral far field pattern becomes progressively broadened as the drive current increases. At the drive current of 1.0 A, the FWHM reaches a value as large as 18.3 degrees from the initial 10 degrees at the drive current of 0.6 A. Additional side lobes appear from right and later from left sides of the center (main lobe). The shape of the far field pattern is essentially non-Gaussian. The portion of the total optical power concentrated in the canal lobe of the far field pattern is only 70% at the 1.0 A drive current.

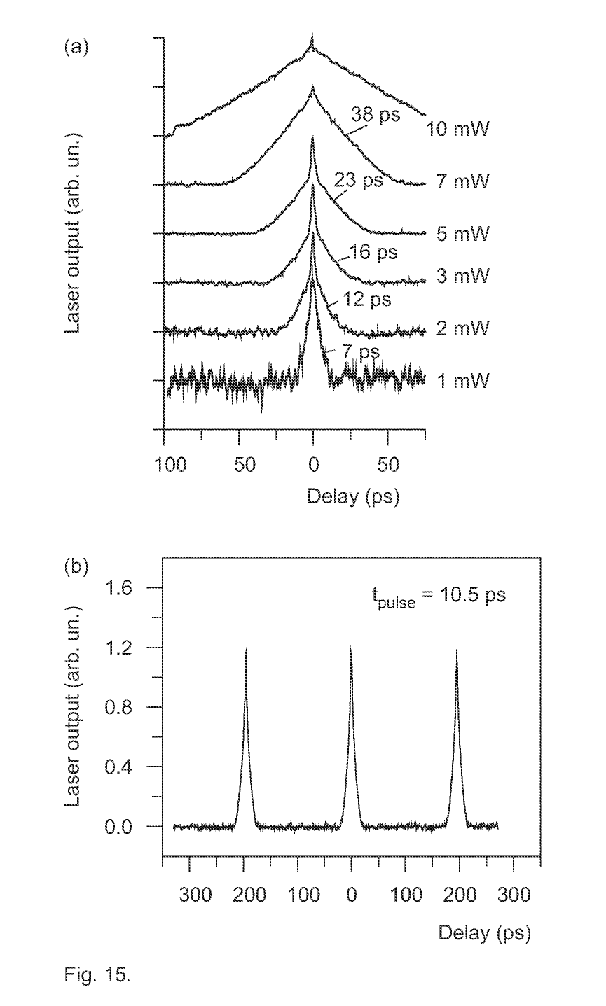

FIGS. 15(a) and 15(b) compare the operation of a prior art mode-locked laser and a three-section mode-locked laser fabricated according to an embodiment of the present invention. FIG. 15(a) represent results for a conventional mode-locked laser having a two-section 5 μm-wide ridge with 8 mm long stripes, where the active section and the absorber section of the device are separated by only a narrow trench, and no filtering effects occur.

In a prior art mode-locked laser, in order to preserve the single lateral mode lasing, one needs to select a rather narrow lateral waveguide. Then, in order to reach a required value of the output power, one needs to increase the drive current. An increase in power also implies an increase in power density. At a high power density, non-linear effects in the propagation of pulses of light become important, and the width of the light pulses increases as shown in FIG. 15(a). This issue is more severe for longer stripes since a lower repetition frequency implies a higher energy for the same average power. Thus, at a power of 7 mW/mirror, the pulse width is 38 ps. The passive section operates at a negative bias of (−4V).

An advantage of using wider stripes is that the same level of power (current) means a lower level of power (current) density. Then it becomes possible to achieve the same average power while nonlinear effects do not affect the functioning of the laser.

FIG. 15(b) show results obtained with a three-section mode-locked laser fabricated according to the embodiment of the present invention shown in FIG. 11. The width of the ridge (1111) and (1131) is 18 μm. The active section (1110) is 8 mm long, the filter section (1120) is 0.5 mm long, and the passive section (1130) is 8 mm long. FIG. 17(b) shows pulses at a repetition frequency of 5.1 GHz and an average power of 6 mW/mirror. The pulse width is 10.5 ps at a zero bias 0 V at the passive section.

Thus, applying the concept of mode filtering and obtaining single-mode lasing at a wide lateral waveguide to a mode-locked laser allows a significant improvement of the performance: 4 times shorter pulses at the same power level.

Although the invention has been illustrated and described with respect to exemplary embodiments thereof, it should be understood by those skilled in the art that the foregoing and various other changes, omissions and additions may be made therein and thereto, without departing from the spirit and scope of the present invention. Therefore, the present invention should not be understood as limited to the specific embodiments set out above but to include all possible embodiments which can be embodied within a scope encompassed and equivalents thereof with respect to the features set out in the appended claims.

1. A semiconductor optoelectronic device comprising:
a) a planar active element;
b) a vertical waveguide surrounding the planar active element in a vertical direction, wherein light is confined in at least one vertical optical mode in a vertical direction along an entire length of the device in a longitudinal direction;
c) a lateral waveguide comprising at least one active section and at least one filter section, wherein the active section and the filter section follow each other in the longitudinal direction;
wherein light is confined in at least two lateral optical modes within the active section;
wherein light is not confined in a lateral direction within the filter section;
d) a first pump element that pumps the planar active element within the active section such that at least a portion of the planar active element within the active section generates optical gain; and
e) a second pump element that pumps at least part of the planar active element within the filter section such that an absorption loss caused by absorption of light by the planar active element within the filter section is lower than approximately 5 cm⁻¹;
wherein light propagates in the longitudinal direction; and
wherein the active section and the filter section are selected such that an amplification per path for at least one preselected lateral optical mode is higher than an amplification per path for the lateral optical modes other than the preselected optical mode.

2. The semiconductor optoelectronic device of claim 1, wherein the preselected lateral optical mode is the fundamental lateral optical mode, such that the device operates as a single lateral mode device.

3. The semiconductor optoelectronic device of claim 1, wherein the amplification per path for the preselected lateral optical mode is larger than the amplification per path for the lateral optical modes other than the preselected lateral optical mode by at least a factor of 2.

4. The semiconductor optoelectronic device of claim 1, wherein the amplification per path for the preselected lateral optical mode is larger than the amplification per path for the lateral optical modes other than the preselected lateral optical mode by at least a factor of 5.

5. The semiconductor optoelectronic device of claim 1, wherein the amplification per path for the preselected lateral optical modes is larger than the amplification per path for the lateral optical modes other than the preselected lateral optical mode by at least a factor of 10.

6. The semiconductor optoelectronic device of claim 1, wherein the vertical waveguide comprises:
a) an optical cavity;
b) a bottom reflector contiguous with the optical cavity; and
c) a top reflector contiguous with the optical cavity on the side opposite the bottom reflector.

7. The semiconductor optoelectronic device of claim 6, wherein the bottom reflector and the top reflector are each selected from the group consisting of:
a) an evanescent reflector; and
b) a multilayered interference reflector.

8. The semiconductor optoelectronic device of claim 1, wherein the lateral waveguide is selected from the group consisting of:
a) a ridge waveguide;
b) a buried waveguide;
c) an oxide confined waveguide; and
d) any combination of a) through c).

9. The semiconductor optoelectronic device of claim 1, wherein the first pump element is an electrical bias element that pumps the planar active element by applying a forward bias to a p-n junction located within the planar active element.

10. The semiconductor optoelectronic device of claim 9, further comprising a plurality of first electrical contacts connected to the active section.

11. The semiconductor optoelectronic device of claim 1, wherein the device is selected from the group consisting of:
a) a semiconductor diode laser;
b) an optical amplifier; and
c) a superluminescent light-emitting diode.

12. The semiconductor optoelectronic device of claim 1, wherein confinement of light in at least two lateral optical modes within the active section is provided by a broad lateral waveguide within the active section.

13. The semiconductor optoelectronic device of claim 12, wherein the broad lateral waveguide is broader than at least two wavelengths of light in a vacuum.

14. The semiconductor optoelectronic device of claim 12, wherein the broad lateral waveguide is broader than at least five wavelengths of light in a vacuum.

15. The semiconductor optoelectronic device of claim 12, wherein the broad lateral waveguide is broader than at least ten wavelengths of light in a vacuum.

16. The semiconductor optoelectronic device of claim 1, wherein the filter section is broader than the active section.

17. The semiconductor optoelectronic device of claim 16, wherein the filter section is broader than the active section by at least a factor of two.

18. The semiconductor optoelectronic device of claim 1, wherein the at least one active section comprises one active section and the at least one filter section comprises one filter section.

19. The semiconductor optoelectronic device of claim 1, wherein the at least one active section comprises two active sections and the at least one filter section comprises one filter section.

20. The semiconductor optoelectronic device of claim 1, wherein the lateral waveguide further comprises at least one absorber section such that the device operates as a mode-locked laser.

21. The semiconductor optoelectronic device of claim 1, wherein the planar active element is selected from the group consisting of:
a) a bulk semiconductor layer;
b) a quantum well;
c) an array of quantum wires;
d) an array of quantum dots; and
e) any combination of a) through d).

22. The semiconductor optoelectronic device of claim 1, wherein the absorption loss is lower than approximately 3 cm⁻¹.

23. The semiconductor optoelectronic device of claim 1, wherein the absorption loss is lower than approximately 1 cm⁻¹.

24. The semiconductor optoelectronic device of claim 1, wherein the second pump element is an electrical bias element that pumps the planar active element by applying a forward bias to a p-n junction located within the planar active element.

25. The semiconductor optoelectronic device of claim 24, further comprising a plurality of first electrical contacts on the active section and a plurality of second electrical contacts on the filter section.

26. The semiconductor optoelectronic device of claim 25, wherein the first and the second electrical contacts are electrically isolated from each other.

27. The semiconductor optoelectronic device of claim 25, wherein the first and the second electrical contacts are electrically connected to each other.

28. The semiconductor optoelectronic device of claim 25, wherein the forward bias applied to the second electrical contact is selected such that the current density, passing through the active element within the filter section approximates a transparency current density of a material of the active element.

29. The semiconductor optoelectronic device of claim 27, wherein a width of the second electrical contact is narrower than a width of the first electrical contact.

30. The semiconductor optoelectronic device of claim 29, wherein the width of the second electrical contact is narrower than the width of the first electrical contact by at least a factor of two.

31. The semiconductor optoelectronic device of claim 29, wherein the width of the second electrical contact is narrower than the width of the first electrical contact by at least a factor of five.

32. The semiconductor optoelectronic device of claim 29, wherein the width of the second electrical contact is narrower than the width of the first electrical contact by at least a factor of ten.

33. The semiconductor optoelectronic device of claim 29, wherein the second electrical contact comprises a plurality of electrically connected electrical subcontacts selected such that a distance between adjacent electrical subcontacts is smaller than a characteristic distance of a charge carrier spread in the active element.

34. The semiconductor optoelectronic device of claim 1, further comprising a tilted output facet for outputting a light beam;
wherein an angle between the output facet and the longitudinal direction does not equal π/2;
wherein the output facet is adjacent to the filter section; and
wherein the active section, the filter section and the output facet are selected such that the output facet of the optoelectronic device is an anti-reflectance facet.

35. The semiconductor optoelectronic device of claim 34, wherein the planar active element is selected from the group consisting of:
a) a bulk semiconductor layer;
b) a quantum well;
c) an array of quantum wires;
d) an array of quantum dots; and
e) any combination of a) through d).

36. The semiconductor optoelectronic device of claim 34, wherein the output facet has a reflectance lower than 1%.

37. The semiconductor optoelectronic device of claim 34, wherein the output facet has a reflectance lower than 0.1%.

38. The semiconductor optoelectronic device of claim 34, wherein the device operates as a single-pass optical amplifier.

39. The semiconductor optoelectronic device of claim 34, wherein the device operates as a super luminescence light-emitting diode.

40. A semiconductor optoelectronic device comprising:
a) a planar active element;
b) a vertical waveguide surrounding the planar active element in a vertical direction, wherein light is confined in at least one vertical optical mode in a vertical direction along an entire length of the device in a longitudinal direction;
c) a lateral waveguide comprising at least one active section and at least one filter section, wherein the active section and the filter section follow each other in the longitudinal direction;
wherein light is confined in at least two lateral optical modes within the active section;
wherein light is not confined in a lateral direction within the filter section;
d) a first pump element that pumps the planar active element within the active section such that at least a portion of the planar active element within the active section generates optical gain;
wherein light propagates in the longitudinal direction;
wherein the active section and the filter section are selected such that an amplification per path for at least one preselected lateral optical mode is higher than an amplification per path for the lateral optical modes other than the preselected optical mode; and
wherein the planar active element has an optical confinement factor in the vertical direction lower than approximately 1.5%.

41. The semiconductor optoelectronic device of claim 40, wherein the preselected lateral optical mode is the fundamental lateral optical mode, such that the device operates as a single lateral mode device.

42. The semiconductor optoelectronic device of claim 40, wherein the amplification per path for the preselected lateral optical mode is larger than the amplification per path for the lateral optical modes other than the preselected lateral optical mode by at least a factor of 2.

43. The semiconductor optoelectronic device of claim 40, wherein the amplification per path for the preselected lateral optical mode is larger than the amplification per path for the lateral optical modes other than the preselected lateral optical mode by at least a factor of 5.

44. The semiconductor optoelectronic device of claim 40, wherein the amplification per path for the preselected lateral optical modes is larger than the amplification per path for the lateral optical modes other than the preselected lateral optical mode by at least a factor of 10.

45. The semiconductor optoelectronic device of claim 40, wherein the vertical waveguide comprises:
a) an optical cavity;
b) a bottom reflector contiguous with the optical cavity; and
c) a top reflector contiguous with the optical cavity on the side opposite the bottom reflector.

46. The semiconductor optoelectronic device of claim 45, wherein the bottom reflector and the top reflector are each selected from the group consisting of:
a) an evanescent reflector; and
b) a multilayered interference reflector.

47. The semiconductor optoelectronic device of claim 40, wherein the lateral waveguide is selected from the group consisting of:
a) a ridge waveguide;
b) a buried waveguide;
c) an oxide confined waveguide; and
d) any combination of a) through c).

48. The semiconductor optoelectronic device of claim 40, wherein the first pump element is an electrical bias element that pumps the planar active element by applying a forward bias to a p-n junction located within the planar active element.

49. The semiconductor optoelectronic device of claim 48, further comprising a plurality of first electrical contacts on the active section.

50. The semiconductor optoelectronic device of claim 40, wherein the device is selected from the group consisting of:
a) a semiconductor diode laser;
b) an optical amplifier; and
c) a superluminescent light-emitting diode.

51. The semiconductor optoelectronic device of claim 40, wherein confinement of light in at least two lateral optical modes within the active section is provided by a broad lateral waveguide within the active section.

52. The semiconductor optoelectronic device of claim 51, wherein the broad lateral waveguide is broader than at least two wavelengths of light in a vacuum.

53. The semiconductor optoelectronic device of claim 51, wherein the broad lateral waveguide is broader than at least five wavelengths of light in a vacuum.

54. The semiconductor optoelectronic device of claim 51, wherein the broad lateral waveguide is broader than at least ten wavelengths of light in a vacuum.

55. The semiconductor optoelectronic device of claim 40, wherein the filter section is broader than the active section.

56. The semiconductor optoelectronic device of claim 55, wherein the filter section is broader than the active section by at least a factor of two.

57. The semiconductor optoelectronic device of claim 40, wherein the at least one active section comprises one active section and the at least one filter section comprises one filter section.

58. The semiconductor optoelectronic device of claim 40, wherein the at least one active section comprises two active sections and the at least one filter section comprises one filter section.

59. The semiconductor optoelectronic device of claim 40, wherein the lateral waveguide further comprises at least one absorber section such that the device operates as a mode-locked laser.

60. The semiconductor optoelectronic device of claim 40, wherein the planar active element is selected from the group consisting of:
a) a bulk semiconductor layer;
b) a quantum well;
c) an array of quantum wires;
d) an array of quantum dots; and
e) any combination of a) through d).

61. The semiconductor optoelectronic device of claim 40, wherein the confinement factor is lower than approximately 1.0%.

62. The semiconductor optoelectronic device of claim 40, wherein the optical confinement factor is lower than approximately 0.5%.

63. The semiconductor optoelectronic device of claim 40, wherein the active element comprises an array of self-organized quantum dots.

64. The semiconductor optoelectronic device of claim 63, wherein a surface density of the quantum dots is a surface density lower than 5×10¹¹ cm⁻².

65. The semiconductor optoelectronic device of claim 63, wherein a surface density of the quantum dots is a surface density lower than 3×10¹¹ cm⁻².

66. The semiconductor optoelectronic device of claim 63, wherein a surface density of the quantum dots is a surface density lower than 1×10¹¹ cm⁻².

67. The semiconductor optoelectronic device of claim 40, wherein the vertical waveguide is an asymmetric narrow waveguide.

68. The semiconductor optoelectronic device of claim 67, wherein the vertical waveguide is narrower than ½ of a cutoff of a second-order vertical optical mode.

69. The semiconductor optoelectronic device of claim 67, wherein the vertical waveguide is narrower than ⅓ of a cutoff of a second-order vertical optical mode.

70. The semiconductor optoelectronic device of claim 67, wherein the vertical waveguide is narrower than ¼ of a cutoff of a second-order vertical optical mode.

71. The semiconductor optoelectronic device of claim 67, wherein a maximum of the fundamental vertical mode is shifted from a center of the vertical waveguide by more than ⅙ of a width of the vertical waveguide.

72. The semiconductor optoelectronic device of claim 67, wherein the maximum of the fundamental vertical mode is shifted from center of the vertical waveguide by more than ¼ of the vertical waveguide width.

73. The semiconductor optoelectronic device of claim 67, wherein the planar active element is selected from the group consisting of:
a) a bulk semiconductor layer;
b) a quantum well;
c) an array of quantum wires;
d) an array of quantum dots; and
e) any combination of a) through d).

74. The semiconductor optoelectronic device of claim 40, further comprising a tilted output facet for outputting a light beam;
wherein an angle between the output facet and the longitudinal direction does not equal π/2;
wherein the output facet is adjacent to the filter section; and
wherein the active section, the filter section and the output facet are selected such that the output facet of the optoelectronic device is an anti-reflectance facet.

75. The semiconductor optoelectronic device of claim 74, wherein the planar active element is selected from the group consisting of:
a) a bulk semiconductor layer;
b) a quantum well;
c) an array of quantum wires;
d) an array of quantum dots; and
e) any combination of a) through d).

77. The semiconductor optoelectronic device of claim 74, wherein the output facet has a reflectance lower than 1%.

78. The semiconductor optoelectronic device of claim 74, wherein the output facet has a reflectance lower than 0.1%.

79. The semiconductor optoelectronic device of claim 74, wherein the device operates as a single-pass optical amplifier.

80. The semiconductor optoelectronic device of claim 74, wherein the device operates as a super luminescence light-emitting diode.

81. A semiconductor optoelectronic device comprising:
a) a planar active element;
b) a vertical waveguide surrounding the planar active element in a vertical direction, wherein light is confined in at least one vertical optical mode in a vertical direction along an entire length of the device in a longitudinal direction;
c) a lateral waveguide comprising at least one active section and at least one filter section, wherein the active section and the filter section follow each other in the longitudinal direction;
wherein light is confined in at least two lateral optical modes within the active section;
wherein light is not confined in a lateral direction within the filter section;
d) a first pump element that pumps the planar active element within the active section such that at least a portion of the planar active element within the active section generates optical gain; and
e) a tilted output facet for outputting a light beam, wherein the filter section is adjacent to the output facet and an angle between the output facet and the longitudinal direction does not equal π/2;
wherein light propagates in the longitudinal direction;
wherein the active section and the filter section are selected such that an amplification per path for at least one preselected lateral optical mode is higher than an amplification per path for the lateral optical modes other than the preselected optical mode;
wherein the active section, the filter section and the output facet are selected such that the output facet of the optoelectronic device is an anti-reflectance facet.

82. The semiconductor optoelectronic device of claim 81, wherein the output facet has a reflectance lower than 1%.

83. The semiconductor optoelectronic device of claim 81, wherein the output facet has a reflectance lower than 0.1%.

84. The semiconductor optoelectronic device of claim 81, wherein the device operates as a single-pass optical amplifier.

85. The semiconductor optoelectronic device of claim 81, wherein the device operates as a super luminescence light-emitting diode.

86. The semiconductor optoelectronic device of claim 81, wherein the planar active element is selected from the group consisting of:
a) a bulk semiconductor layer;
b) a quantum well;
c) an array of quantum wires;
d) an array of quantum dots; and
e) any combination of a) through d).
